(19) United States
(12) Patent Application Publication
(10) Pub. No.: US 2016/0133725 A1
(43) Pub. Date: May 12, 2016

(54) METHOD OF MANUFACTURING THIN-FILM TRANSISTOR, THIN-FILM TRANSISTOR, AND DISPLAY APPARATUS INCLUDING THE SAME

(71) Applicant: Samsung Display Co., Ltd., Yongin-si (KR)

(72) Inventors: Youngjun Chung, Yongin-si (KR); Hyunduck Cho, Yongin-si (KR)

(21) Appl. No.: 14/842,638

(22) Filed: Sep. 1, 2015

(30) Foreign Application Priority Data
Nov. 10, 2014 (KR) 10-2014-0155525

(51) Int. Cl. H01L 29/66; H01L 29/167; H01L 29/45; H01L 21/28; H01L 27/32; H01L 29/10; H01L 29/36; H01L 27/12; H01L 29/417; H01L 29/04; H01L 29/786

(52) U.S. Cl. CPC H01L 29/66757; H01L 29/04; H01L 29/167; H01L 29/45; H01L 21/28017; H01L 29/78675; H01L 29/1095; H01L 29/36; H01L 27/1222; H01L 29/41733; H01L 27/3244

(57) ABSTRACT

A method of manufacturing a thin-film transistor (TFT) having uniform performance in terms of threshold voltage and the like, the TFT, and a display apparatus including the same are disclosed. The method includes: (i) forming a polysilicon layer having a source region, a drain region, and a channel region between the source region and the drain region; (ii) doping a central region in the channel region with a first impurity except for peripheral portions; and (iii) doping the source region and the drain region with a second impurity of a conductivity type that is different from that of the first impurity.

### RELATED APPLICATION

This application claims the benefit of Korean Patent Application No. 10-2014-0155525, filed on Nov. 10, 2014, in the Korean Intellectual Property Office, the disclosure of which is incorporated herein in its entirety by reference.

### BACKGROUND

1. Field

One or more embodiments relate to a method of manufacturing a thin-film transistor (TFT), the TFT, and a display apparatus including the same.

2. Description of the Related Art

In general, a thin-film transistor (TFT) indicates a structure having a silicon layer and gate electrodes. As the silicon layer of the TFT, a polysilicon layer is commonly included, and the polysilicon layer is doped with impurities for required electrical characteristics. At this time, characteristics of the TFT are determined according to a shape of the polysilicon layer, a doping method, and the like.

However, characteristics of existing manufactured TFTs are not uniform. When a display apparatus or the like having the TFTs is implemented, the non-uniformity of the characteristics may cause problems such that an image having non-uniform brightness is displayed even when a same electrical signal is applied to a plurality of pixels.

### SUMMARY

One or more embodiments include a method of manufacturing a thin-film transistor (TFT) having uniform performance in terms of threshold voltage and the like, the TFT, and a display apparatus including the same.

Additional aspects will be set forth in part in the description which follows and, in part, will be apparent from the description, or may be learned by practice of the presented embodiments.

One aspect provides a method of manufacturing a thin-film transistor (TFT), the method comprising: forming a polysilicon layer having a thickness, the polysilicon layer comprising a source forming region, a channel forming region and a drain forming region which are sequentially arranged along edges of the polysilicon layer when viewed in the thickness direction, the channel forming region being disposed between the source forming region and the drain forming region; doping a central portion in the channel forming region with a first impurity, thereby forming a channel region, the central portion being disposed between peripheral portions which extend along the edges of the polysilicon layer when viewed in the thickness direction; and doping the source forming region and the drain forming region with a second impurity of a conductivity type that is different from that of the first impurity, thereby forming a source region and a drain region, respectively.

In the foregoing method, the method may further comprise doping substantially entire portions of the polysilicon layer with the second impurity before doping the central portion. The doping of the first impurity may comprise providing a doping mask having an opening corresponding to the central portion except the peripheral portions. The method may further comprise forming a gate electrode over the channel region between the doping of the central portion and the doping of the source forming region and the drain forming region, wherein the doping of the source forming region and the drain forming region comprises doping the source forming region and the drain forming region by using the gate electrode as a mask. The doping of the source forming region and the drain forming region may comprise doping the source forming region and the drain forming region with the second impurity, except at least a portion of peripheral portions of the source forming region and the drain forming region along the edges of the polysilicon layer, the portion of the peripheral portions of the source forming region and the drain forming region being adjacent to the channel forming region.

Another aspect provides a method of manufacturing a thin-film transistor (TFT), the method comprising: forming a polysilicon layer having a thickness, the polysilicon layer comprising a source forming region, a channel forming region, and a drain forming region which are sequentially arranged along edges of the polysilicon layer when viewed in the thickness direction, the channel forming region being disposed between the source forming region and the drain forming region; doping a central portion in the channel forming region with a first dose of a first impurity, thereby forming a channel region, the central portion being disposed between peripheral portions which extend along the edges of the polysilicon layer when viewed in the thickness direction; and doping the source forming region and the drain forming region with a second dose of the first impurity, thereby forming a source region and a drain region, respectively.

In the foregoing method, the second dose may be greater than the first dose. The method may further comprise doping substantially entire portions of the polysilicon layer with a third dose of the first impurity before the doping of the central region, the third dose being less than the first dose. The doping of the central portion may comprise providing a doping mask having an opening corresponding to the central portion except the peripheral portions. The method may further comprise forming a gate electrode over the channel region between the doping of the central portion and the doping of the source forming region and the drain forming region, wherein the doping of the source forming region and the drain forming region comprises doping the source forming region and the drain forming region by using the gate electrode as a mask. The doping of the source forming region and the drain forming region may comprise doping the source forming region and the drain forming region with the second dose of the first impurity, except at least a portion of peripheral portions of the source forming region and the drain forming region along the edges of the polysilicon layer, the portion of the peripheral portions of the source forming region and the drain forming region being adjacent to the channel forming region.

Still another aspect provides a thin-film transistor (TFT) comprising: a polysilicon layer comprising: a source region, a drain region, and a channel region disposed between the source region and the drain region when viewed in a thickness direction of the polysilicon layer, wherein the source region, the channel region, and the drain region are sequentially arranged along edges of the polysilicon layer when viewed in the thickness direction, wherein the channel region comprises a central portion doped with a first impurity and peripheral portions extending along the edges of the polysilicon layer, the central portion being disposed between the peripheral portions when viewed in the thickness direction, wherein the source region and the drain region are doped with a second impurity of a conductivity type that is different from that of the first impurity; and a gate electrode overlapping the channel region of the polysilicon layer when viewed in the thickness direction.

In the foregoing TFT, the peripheral portions of the channel region are not doped with the first impurity. The peripheral portions of the channel region may be doped with the second impurity. A doping concentration in the source region and the drain region of the polysilicon layer may be higher than that in the peripheral portions of the channel region.

A further aspect provides a thin-film transistor (TFT) comprising: a polysilicon layer comprising: a source region, a drain region, and a channel region disposed between the source region and the drain region when viewed in a thickness direction of the polysilicon layer, wherein the source region, the channel region, and the drain region are sequentially arranged along edges of the polysilicon layer when viewed in the thickness direction, wherein the channel region comprises a central portion doped with a first impurity of a first doping concentration and peripheral portions extending along the edges of the polysilicon layer, wherein the source region and the drain region are doped with the first impurity of a second doping concentration that is different from the first doping concentration; and a gate electrode overlapping the channel region of the polysilicon layer when viewed in the thickness direction.

In the foregoing TFT, the second doping concentration may be greater than the first doping concentration. The peripheral portions of the channel region are not doped with the first impurity. The peripheral portions of the channel region may be doped with the first impurity of a third doping concentration that is less than the first doping concentration. The central portion of the channel region is configured to allow charge carriers to pass therethrough from the source region to the drain region, wherein the peripheral regions of the channel region may be configured to inhibit charge carriers from passing therethrough from the source region to the drain region.

According to one or more embodiments, a method of manufacturing a thin-film transistor includes: (i) forming a polysilicon layer having a source region, a drain region, and a channel region between the source region and the drain region; (ii) doping a central region in the channel region with a first impurity except for portions connecting the source region and the drain region along edges of the polysilicon layer; and (iii) doping the source region and the drain region with a second impurity of a conductivity type that is different from that of the first impurity.

The method may further include doping the polysilicon layer with the second impurity before the doping of the central region.

The doping of the first impurity may include using a doping mask having an opening corresponding to the central region except for the portions connecting the source region and the drain region along the edges of the polysilicon layer in the channel region.

The method may further include forming a gate electrode corresponding to the channel region between the doping of the central region and the doping of the source region and the drain region, wherein the doping of the source region and the drain region includes doping the source region and the drain region by using the gate electrode as a mask.

The doping of the source region and the drain region may include doping a portion in the source region and the drain region with the second impurity except for at least a portion adjacent to the channel region as the edges of the polysilicon layer.

According to one or more embodiments, a method of manufacturing a thin-film transistor includes: (i) forming a polysilicon layer having a source region, a drain region, and a channel region between the source region and the drain region; (ii) doping a central region in the channel region with a first dose of a first impurity except for portions connecting the source region and the drain region along edges of the polysilicon layer; and (iii) doping the source region and the drain region with a second dose of the first impurity.

The second dose may be greater than the first dose.

The method may further include doping the polysilicon layer with a third dose of the first impurity before the doping of the central region, the third dose being less than the first dose.

The doping of the central region may include using a doping mask having an opening corresponding to the central region except for the portions connecting the source region and the drain region along the edges of the polysilicon layer in the channel region.

The method may further include forming a gate electrode corresponding to the channel region between the doping of the central region and the doping of the source region and the drain region, wherein the doping of the source region and the drain region includes doping the source region and the drain region by using the gate electrode as a mask.

The doping of the source region and the drain region may include doping a portion in the source region and the drain region with the second dose of the first impurity except for at least a portion adjacent to the channel region as the edges of the polysilicon layer.

According to one or more embodiments, a thin-film transistor includes: (i) a polysilicon layer having a source region, a drain region, and a channel region between the source region and the drain region, doped with a first impurity in a central region except for portions connecting the source region and the drain region along edges of the polysilicon layer in the channel region, and doped with a second impurity of a conductivity type that is different from that of the first impurity in the source region and the drain region; and (ii) a gate electrode corresponding to the channel region of the polysilicon layer.

The portions connecting the source region and the drain region along edges of the polysilicon layer in the channel region of the polysilicon layer may not be doped.

The portions connecting the source region and the drain region along edges of the polysilicon layer in the channel region of the polysilicon layer may be doped with the second impurity.

A doping concentration in the source region and the drain region of the polysilicon layer may be higher than that in the portions connecting the source region and the drain region along the edges of the polysilicon layer in the channel region of the polysilicon layer.

According to one or more embodiments, a thin-film transistor includes: (i) a polysilicon layer having a source region, a drain region, and a channel region between the source region and the drain region, doped with a first impurity of a first doping concentration in a central region except for portions connecting the source region and the drain region along edges of the polysilicon layer in the channel region, and doped with the first impurity of a second doping concentration that is different from the first doping concentration in the source region and the drain region; and (ii) a gate electrode corresponding to the channel region of the polysilicon layer.

The second doping concentration may be greater than the first doping concentration.

The portions connecting the source region and the drain region along the edges of the polysilicon layer in the channel region of the polysilicon layer may not be doped.

The portions connecting the source region and the drain region along the edges of the polysilicon layer in the channel region of the polysilicon layer may be doped with the first impurity of a third doping concentration that is less than the first doping concentration.

According to one or more embodiments, a display apparatus includes: at least one of the thin-film transistors described above; and a display element electrically connected to the at least one thin-film transistor.

### BRIEF DESCRIPTION OF THE DRAWINGS

These and/or other aspects will become apparent and more readily appreciated from the following description of the embodiments, taken in conjunction with the accompanying drawings in which:

FIGS. 1 to 4 are conceptual top views illustrating processes of methods of manufacturing a thin-film transistor (TFT), according to embodiments of the inventive concept;

FIG. 5 is a conceptual top view illustrating a process of methods of manufacturing a TFT, according to other embodiments of the inventive concept;

FIG. 6 is a conceptual top view illustrating a process of methods of manufacturing a TFT, according to other embodiments of the inventive concept; and

FIG. 7 is a cross-sectional view of a portion of a display apparatus according to an embodiment of the inventive concept.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description.

It will be understood that when a layer, region, or component is referred to as being “formed on,” another layer, region, or component, it can be directly or indirectly formed on the other layer, region, or component. That is, for example, intervening layers, regions, or components may be present. Sizes of elements in the drawings may be exaggerated for convenience of explanation. In other words, since sizes and thicknesses of components in the drawings are arbitrarily illustrated for convenience of explanation, the following embodiments are not limited thereto.

In the following examples, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

As used herein, the term “and/or” includes any and all combinations of one or more of the associated listed items. Expressions such as “at least one of,” when preceding a list of elements, modify the entire list of elements and do not modify the individual elements of the list.

In embodiments, a display panel includes a substrate, an array of pixels disposed over the substrate, and an array of switching circuits. Each of the switching circuits is to switch one of the pixels and includes at least a thin-film transistor. Various examples of the thin-film transistor are described below in detail.

FIGS. 1 to 4 are conceptual top views illustrating processes of methods of manufacturing a thin-film transistor (TFT), according to embodiments of the inventive concept.

First, as shown in FIG. 1, a polysilicon layer 10 is formed on a substrate. The substrate may include glass, plastic, or a metal, and a buffer layer including silicon oxide, silicon nitride, or the like may be formed on the substrate according to circumstances, and the polysilicon layer 10 may be formed on the buffer layer. The polysilicon layer 10 may be formed by forming and crystallizing an amorphous silicon layer. The polysilicon layer 10 may have various shapes, e.g., a shape extending in one direction (x-axis direction) as shown in FIG. 1 or a curved shape. In any case, the polysilicon layer 10 has a source region 10S, a drain region 10D, and a channel region 10C between the source region 10S and the drain region 10D. In the illustrated embodiments, the source region 10S, the channel region 10C and the drain region 10D are sequentially arranged along two side edges.

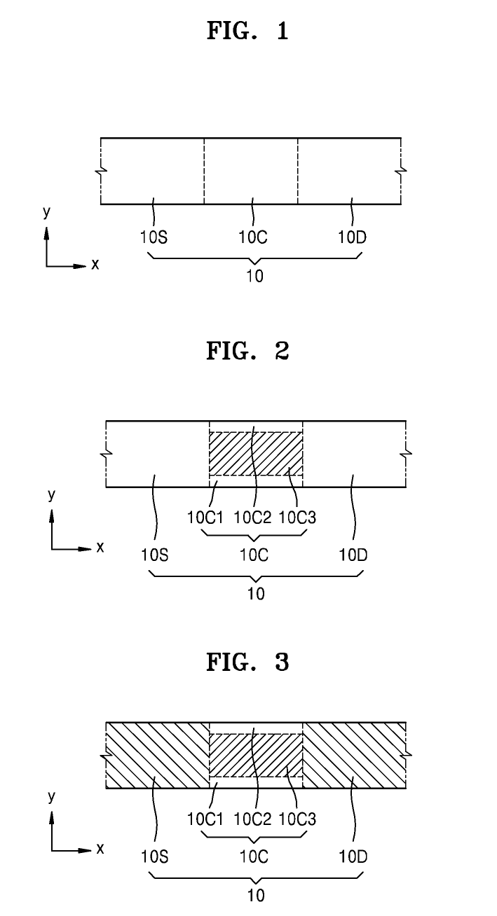

Thereafter, as shown in FIG. 2, the channel region 10C is doped with a first impurity. In detail, a central region 1003 in the channel region 10C except for peripheral portions 1001 and 1002 is doped with the first impurity. In the illustrated embodiments, the central region extends from the source region to the drain region. Also, each of the peripheral portions extends from the source region to the drain region along one of the edges. The first impurity may be, for example, phosphorous (P), arsenic (As), or antimony (Sb) or boron (B), aluminum (Al), indium (In), or gallium (Ga). For the former, the TFT becomes an N-type TFT wherein electrons are carriers, and for the latter, the TFT becomes a P-type TFT wherein holes are carriers. In any case, only the central region 1003 except for the peripheral portions 1001 and 1002 is doped with the first impurity. To this end, a doping mask having an opening corresponding to the central region 1003 in the channel region 10C except for the peripheral portions 1001 and 1002 may be used.

Thereafter, as shown in FIG. 3, the source region 10S and the drain region 10D are doped with a second impurity of a conductivity type that is different from that of the first impurity. For example, when the central region 1003 of the channel region 10C is doped with P, As, Sb, or the like, the source region 10S and the drain region 10D may be doped with B, Al, In, Ga, or the like. The source region 10S and the drain region 10D may contact with separate source and drain electrodes or may act as the source and drain electrodes, respectively. In addition, an extended portion extending from the source region 10S and/or the drain region 10D may be provided and also be doped such that the doped extended portion acts as a wiring connected to the TFT.

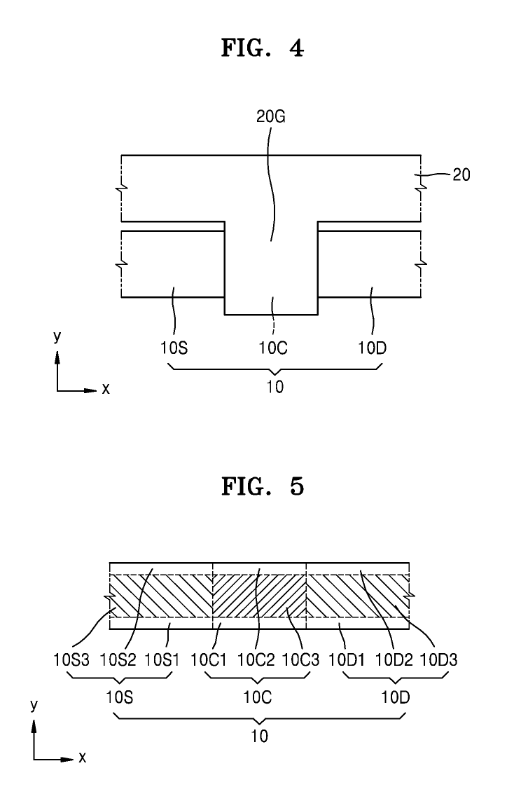

When the source region 10S and the drain region 10D are doped, the channel region 10C should not be doped, and to this end, the source region 10S and the drain region 10D may be doped using a mask shielding the channel region 10C. If a gate electrode 20G is located on the polysilicon layer 10, the gate electrode 20G may be first formed as shown in FIG. 4 before doping the source region 10S and the drain region 10D. In this case, the gate electrode 20G is located on the polysilicon layer 10 and has a shape corresponding to the channel region 10C, and accordingly, the channel region 10C is shielded by the gate electrode 20G, and thus, the source region 10S and the drain region 10D may be doped using the gate electrode 20G as a mask. Of course, when the gate electrode 20G is formed, a gate wiring 20 connected to the gate electrode 20G may also be formed of the same material and on the same layer as that of the gate electrode 20G at the same time.

For the TFT manufactured by the TFT manufacturing method according to the present embodiment described above, only the central region 10C3 in the channel region 10C except for the peripheral portions 10C1 and 10C2 is doped. Accordingly, when a plurality of TFTs are manufactured, electrical characteristics, such as a threshold voltage and the like, of the TFTs may be uniformly maintained.

In detail, when the polysilicon layer 10 patterned as shown in FIG. 1 is formed, shapes of the edges of the polysilicon layer 10 may not be maintained unchanged during a patterning process. For example, unlike FIG. 1, the edges of the polysilicon layer 10 may not be in rectangular shapes in the x-axis direction such that a portion of the edges of the polysilicon layer 10 may be broken or hollowed. Alternatively, an angle between a side surface of the edges of the polysilicon layer 10 and an upper surface of the substrate (as a result, an upper surface of the polysilicon layer 10) may not be uniformly maintained. In this case, if the entire polysilicon layer 10 is doped with the first impurity, carriers moving near the edges of the polysilicon layer 10 in the channel region 10C may be influenced by the shape of the edges of the polysilicon layer 10, thereby resulting in non-uniform electrical characteristics, such as a threshold voltage and the like, of the TFTs.

However, in the method of manufacturing a TFT, according to the present embodiment, only the central region 1003 in the channel region 10C except for the peripheral portions 1001 and 1002 is doped with the first impurity. Accordingly, when the TFT operates, carriers moving in the channel region 10C move through the central region 1003 which is a doped portion of the channel region 100. As a result, even if an unpredicted deformation occurs at the edges of the polysilicon layer 10, the carriers may not be influenced or may be minimally influenced due to the deformation. Therefore, a TFT having uniform electrical characteristics may be manufactured.

Alternatively, after forming the polysilicon layer 10 as shown in FIG. 1, the polysilicon layer 10 may be doped with the second impurity before doping the channel region 10C. A dose of the second impurity in this case may be less than a dose of the second impurity when the source region 10S and the drain region 10D are doped in the future.

When a TFT is manufactured through this process, only the central region 1003 in the channel region 10C except for the peripheral portions 1001 and 1002 is doped with the first impurity, and the peripheral portions 1001 and 1002 are doped with the second impurity of a conductivity type which is different from that of the first impurity. Accordingly, when the TFT operates, it may be further clear that carriers originated in the conductivity type of the first impurity move only in the central region 1003 doped with the first impurity without moving into the edge portions 1001 and 1002 doped with the second impurity when the carriers move in the channel region 100.

Alternatively, when the source region 10S and the drain region 10D are doped, instead of doping the whole source and drain regions 10S and 10D as shown in FIG. 3, it may be considered to dope only a portion of each of the source and drain regions 10S and 10D as shown in FIG. 5. In detail, in the source region, only a portion 10S3 except for edge portions 1051 and 10S2 may be doped with the second impurity. In the drain region, a portion 10D3 except for edge portions 10D1 and 10D2 may be doped with the second impurity. By doing this, an influence to electrical characteristics due to a deformation of the edges of the polysilicon layer 10 may be prevented or minimized even in the source region 10S and the drain region 10D.

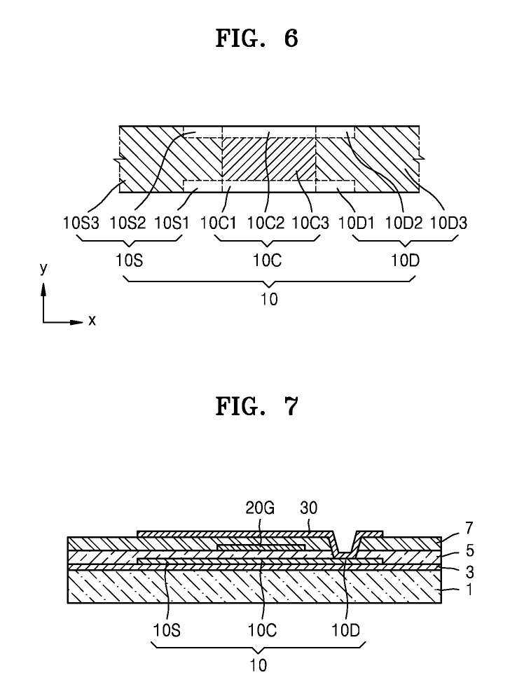

Alternatively, when the source region 10S and the drain region 10D are doped, it may be considered to dope only a portion of each of the source and drain regions 10S and 10D as shown in FIG. 6. In detail, only a portion 10S3 except for side portions 10S1 and 10S2 of the polysilicon layer 10 in the source region 10S and a portion 10D3 except for side portions 10D1 and 10D2 of the polysilicon layer 10 in the drain region 10D may be doped with the second impurity. Here, the side portions 10S1 and 10S2 are parts of the peripheral portions of the source forming region which are adjacent to the channel region 10C, and the side portions 10D1 and 10D2 are parts of the peripheral portions of the drain forming region which are adjacent to the channel region 10C. This is to prevent or minimize an influence to electrical characteristics due to a deformation of the edges of the polysilicon layer 10 in a region adjacent to the channel region 10C since a portion which defines the electrical characteristics of a TFT is the channel region 10C.

A method of manufacturing a TFT, according to another embodiment of the inventive concept, will now be described with reference to FIGS. 1 to 4.

Likewise, as shown in FIG. 1, the polysilicon layer 10 having the source region 10S, the drain region 10D, and the channel region 10C between the source region 10S and the drain region 10D is formed. Thereafter, as shown in FIG. 2, the central region 10C3 in the channel region 10C except for the peripheral portions 10C1 and 10C2 is doped with a first dose of the first impurity. To this end, a doping mask having an opening corresponding to the central region 10C3 in the channel region 10C except for the peripheral portions 10C1 and 10C2 may be used.

Thereafter, as shown in FIG. 3, the source region 10S and the drain region 10D are doped with a second dose of the first impurity. In this case, the second dose is greater than the first dose. In order for the expanding portion of each of the source and drain regions 10S and 10D to act as a wiring, the source region 10S and the drain region 10D should have conductivity, and to this end, it is necessary to increase a dose during doping of the source region 10S and the drain region 10D.

When the source region 10S and the drain region 10D are doped, the channel region 10C should not be doped, and to this end, a mask for shielding the channel region 10C may be used when the source region 10S and the drain region 10D are doped. Alternatively, if the gate electrode 20G is located on the polysilicon layer 10, the gate electrode 20G may be first formed as shown in FIG. 4 before doping the source region 10S and the drain region 10D. In this case, the gate electrode 20G is located on the polysilicon layer 10 and has a shape corresponding to the channel region 10C, and accordingly, the channel region 10C is shielded by the gate electrode 20G, and thus, the source region 10S and the drain region 10D may be doped using the gate electrode 20G as a mask. Of course, when the gate electrode 20G is formed, the gate wiring 20 connected to the gate electrode 20G may also be formed of the same material and on the same layer as that of the gate electrode 20G at the same time.

For the TFT manufactured according to the TFT manufacturing method according to the present embodiment, when carriers originated in the first impurity move in the channel region 10C, the carriers move through the central region 10C3 which is a doped portion of the channel region 10C. As a result, even if an unpredicted deformation occurs at the edges of the polysilicon layer 10, the carriers may not be influenced or may be minimally influenced due to the deformation. Therefore, a TFT having uniform electrical characteristics may be manufactured.

Alternatively, after forming the polysilicon layer 10 as shown in FIG. 1, the polysilicon layer 10 may be doped with the first impurity of a third dose that is less than the first dose before doping the channel region 100.

When the source region 10S and the drain region 10D are doped, instead of doping the whole source and drain regions 10S and 10D as shown in FIG. 3, it may be considered to dope only a portion of each of the source and drain regions 10S and 10D as shown in FIG. 5. In detail, only the portion 10S3 except for the edge portions 1051 and 10S2 of the polysilicon layer 10 in the source region 10S and the portion 10D3 except for the edge portions 10D1 and 10D2 of the polysilicon layer 10 in the drain region 10D may be doped with the first impurity. By doing this, an influence to electrical characteristics due to a deformation of the edges of the polysilicon layer 10 may be prevented or minimized even in the source region 10S and the drain region 10D.

Alternatively, when the source region 10S and the drain region 10D are doped, it may be considered to dope only a portion of each of the source and drain regions 10S and 10D as shown in FIG. 6. In detail, only the portion 10S3 except for the peripheral portions 1051 and 10S2 of the polysilicon layer 10 in the source region 10S and the portion 10D3 except for the peripheral portions 10D1 and 10D2 of the polysilicon layer 10 in the drain region 10D may be doped with the first impurity. Here, the side portions 1051 and 1052 are parts of the peripheral portions of the source region 10S which are adjacent to the channel region 10C, and the side portions 10D1 and 10D2 are parts of the peripheral portions of the drain region 10D which are adjacent to the channel region 10C. This is to prevent or minimize an influence to electrical characteristics due to a deformation of the edges of the polysilicon layer 10 in a region adjacent to the channel region 10C since a portion which defines the electrical characteristics of a TFT is the channel region 10C.

Although the methods of manufacturing a TFT have been described, methods of manufacturing a display apparatus by using the above-described methods also belong to the scope of the inventive concept. A display apparatus may be manufactured by forming a TFT by any of the above-described methods and forming a pixel electrode electrically connected to the TFT.

Of course, the TFTs also belong to the scope of the inventive concept. The TFTs will now be described.

A TFT according to an embodiment of the inventive concept includes the polysilicon layer 10 and the gate electrode 20G. The polysilicon layer 10 has the source region 10S, the drain region 10D, and the channel region 10C between the source region 10S and the drain region 10D. The central region 10C3 in the channel region 10C except for the peripheral portions 10C1 and 10C2 is doped with the first impurity, and the source region 10S and the drain region 10D are doped with the second impurity of a conductivity type that is different from that of the first impurity. In addition, the gate electrode 20G is disposed to correspond to the channel region 10C of the polysilicon layer 10.

For the TFT according to the present embodiment, only the central region 10C3 in the channel region 10C except for the peripheral portions 10C1 and 10C2 is doped with the first impurity, and the peripheral portions 1001 and 1002 are not doped. Accordingly, when the TFT operates, carriers moving in the channel region 10C move through the central region 1003 which is a doped portion of the channel region 100. As a result, even if an unpredicted deformation occurs at the edges of the polysilicon layer 10, the carriers may not be influenced or may be minimally influenced due to the deformation. Therefore, the TFT according to the present embodiment has uniform electrical characteristics.

Alternatively, the peripheral portions 1001 and 1002 may be doped with the second impurity. In this case, a doping concentration of the peripheral portions 1001 and 1002 may be less than a doping concentration of the source and drain regions 10S and 10D of the polysilicon layer 10. This is because the channel region 10C should have a semiconductor characteristic while the source and drain regions 10S and 10D of the polysilicon layer 10 and/or an extended portion extending from each of the source and drain regions 10S and 10D should have conductivity as a portion of a wiring.

For the TFT, when the TFT operates, it may be further clear that carriers originated in the conductivity type of the first impurity move only in the central region 1003 doped with the first impurity without moving into the edge portions 1001 and 1002 doped with the second impurity when the carriers move in the channel region 100.

For a TFT according to another embodiment of the inventive concept, instead of doping the whole source and drain regions 10S and 10D as shown in FIG. 3, only a portion of each of the source and drain regions 10S and 10D may be doped as shown in FIG. 5. In detail, only the portion 10S3 except for the edge portions 1051 and 10S2 of the polysilicon layer 10 in the source region 10S and the portion 10D3 except for the edge portions 10D1 and 10D2 of the polysilicon layer 10 in the drain region 10D may be doped with the second impurity. By doing this, an influence to electrical characteristics due to a deformation of the edges of the polysilicon layer 10 may be prevented or minimized even in the source region 10S and the drain region 10D.

Alternatively, only a portion of each of the source and drain regions 10S and 10D may be doped as shown in FIG. 6. In detail, only the portion 10S3 except for the peripheral portions 1051 and 10S2 of the polysilicon layer 10 in the source region 10S and the portion 10D3 except for the peripheral portions 10D1 and 10D2 of the polysilicon layer 10 in the drain region 10D may be doped with the second impurity. This is to prevent or minimize an influence to electrical characteristics due to a deformation of the edges of the polysilicon layer 10 in a region adjacent to the channel region 10C since a portion which defines the electrical characteristics of the TFT is the channel region 10C.

A TFT according to another embodiment of the inventive concept will now be described. The TFT according to the present embodiment also includes the polysilicon layer 10 and the gate electrode 20G. The polysilicon layer 10 has the source region 10S, the drain region 10D, and the channel region 10C between the source region 10S and the drain region 10D. The central region 1003 in the channel region 10C except for the peripheral portions 1001 and 1002 is doped with the first impurity of a first doping concentration, and the source region 10S and the drain region 10D are doped with the first impurity of a second doping concentration that is different from the first doping concentration. In addition, the gate electrode 20G is disposed to correspond to the channel region 10C of the polysilicon layer 10. The second doping concentration is greater than the first doping concentration.

For the TFT according to the present embodiment, only the central region 1003 in the channel region 10C except for the peripheral portions 1001 and 1002 is doped with the first impurity, and the peripheral portions 1001 and 1002 are not doped. Accordingly, when the TFT operates, carriers moving in the channel region 10C move through the central region 1003 which is a doped portion of the channel region 100. As a result, even if an unpredicted deformation occurs at the edges of the polysilicon layer 10, the carriers may not be influenced or may be minimally influenced due to the deformation. Therefore, the TFT according to the present embodiment has uniform electrical characteristics.

Alternatively, the peripheral portions 1001 and 1002 may be doped with the first impurity of a third doping concentration.

For a TFT according to another embodiment of the inventive concept, instead of doping the whole source and drain regions 10S and 10D as shown in FIG. 3, only a portion of each of the source and drain regions 10S and 10D may be doped as shown in FIG. 5. In detail, only the portion 10S3 except for the edge portions 1051 and 10S2 of the polysilicon layer 10 in the source region 10S and the portion 10D3 except for the edge portions 10D1 and 10D2 of the polysilicon layer 10 in the drain region 10D may be doped with the first impurity. By doing this, an influence to electrical characteristics due to a deformation of the edges of the polysilicon layer 10 may be prevented or minimized even in the source region 10S and the drain region 10D.

Alternatively, only a portion of each of the source and drain regions 10S and 10D may be doped as shown in FIG. 6. In detail, only the portion 10S3 except for the peripheral portions 1051 and 10S2 of the polysilicon layer 10 in the source region 10S and the portion 10D3 except for the peripheral portions 10D1 and 10D2 of the polysilicon layer 10 in the drain region 10D may be doped with the first impurity. This is to prevent or minimize an influence to electrical characteristics due to a deformation of the edges of the polysilicon layer 10 in a region adjacent to the channel region 10C since a portion which defines the electrical characteristics of the TFT is the channel region 100.

Although the TFTs have been described, the above-described embodiments are not limited thereto. For example, as shown in FIG. 7 which is a cross-sectional view of a portion of a display apparatus, a display apparatus having at least one of the TFTs according to the above-described embodiments and a display element electrically connected thereto also belongs to the scope of the inventive concept.

Referring to FIG. 7, the display apparatus according to the present embodiment may include: a TFT having the polysilicon layer 10 doped as described above with reference to the TFTs according to the above-described embodiments and the gate electrode 20G; and a pixel electrode 30 connected to the source region 10S or the drain region 10D of the TFT. Of course, a buffer layer 3 may be interposed between a substrate 1 and the polysilicon layer 10, a gate insulating layer 5 may be interposed between the polysilicon layer 10 and the gate electrode 20G, and an insulating layer, a protective layer, or a planarization layer 7 may be interposed between the gate electrode 20G and the pixel electrode 30.

A liquid crystal material or an intermediate layer including an emission layer may be disposed on the pixel electrode 30. An opposite electrode may be disposed on the liquid crystal material or the intermediate layer. When the liquid crystal material is disposed on the pixel electrode 30, the display apparatus may be a liquid crystal display apparatus, and when the intermediate layer including an emission layer is disposed on the pixel electrode 30, the display apparatus may be an organic light-emitting display apparatus.

For the display apparatus, since electrical characteristics of TFTs for controlling operations of respective pixels may be uniform, an image may be further accurately reproduced.

As described above, according to the one or more of the above embodiments, a method of manufacturing a thin-film transistor having uniform performance in terms of threshold voltage and the like, the thin-film transistor, and a display apparatus including the same may be implemented. Of course, the scope of the inventive concept is not limited by the effects.

It should be understood that the embodiments described therein should be considered in a descriptive sense only and not for purposes of limitation. Descriptions of features or aspects within each embodiment should typically be considered as available for other similar features or aspects in other embodiments.

While one or more embodiments have been described with reference to the figures, it will be understood by those of ordinary skill in the art that various changes in form and details may be made therein without departing from the spirit and scope as defined by the following claims.

What is claimed is:

1. A method of manufacturing a thin-film transistor (TFT), the method comprising:
forming a polysilicon layer having a thickness, the polysilicon layer comprising a source forming region, a channel forming region, and a drain forming region which are sequentially arranged along edges of the polysilicon layer when viewed in the thickness direction, the channel forming region being disposed between the source forming region and the drain forming region;
doping a central portion in the channel forming region with a first impurity, thereby forming a channel region, the central portion being disposed between peripheral portions which extend along the edges of the polysilicon layer when viewed in the thickness direction; and
doping the source forming region and the drain forming region with a second impurity of a conductivity type that is different from that of the first impurity, thereby forming a source region and a drain region, respectively.

2. The method of claim 1, further comprising doping substantially entire portions of the polysilicon layer with the second impurity before doping the central portion.

3. The method of claim 1, wherein the doping of the first impurity comprises providing a doping mask having an opening corresponding to the central portion except the peripheral portions.

4. The method of claim 1, further comprising forming a gate electrode over the channel region between the doping of the central portion and the doping of the source forming region and the drain forming region,
wherein the doping of the source forming region and the drain forming region comprises doping the source forming region and the drain forming region by using the gate electrode as a mask.

5. The method of claim 1, wherein the doping of the source forming region and the drain forming region comprises doping the source forming region and the drain forming region with the second impurity, except at least a portion of peripheral portions of the source forming region and the drain forming region along the edges of the polysilicon layer, the portion of the peripheral portions of the source forming region and the drain forming region being adjacent to the channel forming region.

6. A method of manufacturing a thin-film transistor (TFT), the method comprising:
forming a polysilicon layer having a thickness, the polysilicon layer comprising a source forming region, a channel forming region, and a drain forming region which are sequentially arranged along edges of the polysilicon layer when viewed in the thickness direction, the channel forming region being disposed between the source forming region and the drain forming region;
doping a central portion in the channel forming region with a first dose of a first impurity, thereby forming a channel region, the central portion being disposed between peripheral portions which extend along the edges of the polysilicon layer when viewed in the thickness direction; and
doping the source forming region and the drain forming region with a second dose of the first impurity, thereby forming a source region and a drain region, respectively.

7. The method of claim 6, wherein the second dose is greater than the first dose.

8. The method of claim 6, further comprising doping substantially entire portions of the polysilicon layer with a third dose of the first impurity before the doping of the central region, the third dose being less than the first dose.

9. The method of claim 6, wherein the doping of the central portion comprises providing a doping mask having an opening corresponding to the central portion except the peripheral portions.

10. The method of claim 6, further comprising forming a gate electrode over the channel region between the doping of the central portion and the doping of the source forming region and the drain forming region,
wherein the doping of the source forming region and the drain forming region comprises doping the source forming region and the drain forming region by using the gate electrode as a mask.

11. The method of claim 6, wherein the doping of the source forming region and the drain forming region comprises doping the source forming region and the drain forming region with the second dose of the first impurity, except at least a portion of peripheral portions of the source forming region and the drain forming region along the edges of the polysilicon layer, the portion of the peripheral portions of the source forming region and the drain forming region being adjacent to the channel forming region.

12. A thin-film transistor (TFT) comprising:
a polysilicon layer comprising:
a source region,
a drain region, and
a channel region disposed between the source region and the drain region when viewed in a thickness direction of the polysilicon layer,
wherein the source region, the channel region, and the drain region are sequentially arranged along edges of the polysilicon layer when viewed in the thickness direction,
wherein the channel region comprises a central portion doped with a first impurity and peripheral portions extending along the edges of the polysilicon layer, the central portion being disposed between the peripheral portions when viewed in the thickness direction,
wherein the source region and the drain region are doped with a second impurity of a conductivity type that is different from that of the first impurity; and
a gate electrode overlapping the channel region of the polysilicon layer when viewed in the thickness direction.

13. The TFT of claim 12, wherein the peripheral portions of the channel region are not doped with the first impurity.

14. The TFT of claim 12, wherein the peripheral portions of the channel region are doped with the second impurity.

15. The TFT of claim 14, wherein a doping concentration in the source region and the drain region of the polysilicon layer is higher than that in the peripheral portions of the channel region.

16. A thin-film transistor (TFT) comprising:
a polysilicon layer comprising:
a source region,
a drain region, and
a channel region disposed between the source region and the drain region when viewed in a thickness direction of the polysilicon layer,
wherein the source region, the channel region and the drain region are sequentially arranged along edges of the polysilicon layer when viewed in the thickness direction,
wherein the channel region comprises a central portion doped with a first impurity of a first doping concentration and peripheral portions extending along the edges of the polysilicon layer,
wherein the source region and the drain region are doped with the first impurity of a second doping concentration that is different from the first doping concentration; and
a gate electrode overlapping the channel region of the polysilicon layer when viewed in the thickness direction.

17. The TFT of claim 16, wherein the second doping concentration is greater than the first doping concentration.

18. The TFT of claim 16, wherein the peripheral portions of the channel region are not doped with the first impurity.

19. The TFT of claim 16, wherein the peripheral portions of the channel region are doped with the first impurity of a third doping concentration that is less than the first doping concentration.

20. A display device comprising:
a substrate;
an array of pixels disposed over the substrate;
an array of switching circuits, each of which is configured to switch one of the pixels, each switching circuit comprising the TFT of claim 12.
